(19) United States
(12) Patent Application Publication
(10) Pub. No.: US 2016/0181011 A1
(43) Pub. Date: Jun. 23, 2016

(54) COMPOSITE ELECTRONIC COMPONENT

(71) Applicant: SAMSUNG ELECTRO-MECHANICS CO., LTD., Suwon-Si (KR)

(72) Inventors: Yu Jin CHOI, Suwon-Si (KR); Min Kyoung CHEON, Suwon-Si (KR); Soo Hwan SON, Suwon-Si (KR); Ho Yoon KIM, Suwon-Si (KR)

(21) Appl. No.: 14/887,043

(22) Filed: Oct. 19, 2015

(30) Foreign Application Priority Data
Dec. 23, 2014 (KR) 10-2014-0186907

(51) Int. Cl. H01F 27/40; H01F 27/24; H01G 4/248; H01G 4/30; H01G 4/232; H01G 4/005; H01F 27/28; H05K 1/18

(52) U.S. Cl. CPC H01F 27/40; H01F 27/2804; H01F 27/24; H05K 1/181; H01G 4/30; H01G 4/232; H01G 4/005; H01G 4/248

(57) ABSTRACT

A composite electronic component includes a composite body including a capacitor and an inductor bonded to each other; an input terminal disposed on a first end surface of the composite body and connected to the coil part of the inductor; an output terminal including a first output terminal disposed on a second end surface of the composite body and connected to the coil part of the inductor and a second output terminal disposed on the second end surface of the composite body and connected to the first internal electrodes of the capacitor; and a ground terminal disposed on the first end surface of the composite body and connected to the second internal electrodes of the capacitor. A bonded surface between the inductor and the capacitor is provided with insulating layers.

### CROSS-REFERENCE TO RELATED APPLICATION

This application claims the benefit of priority to Korean Patent Application No. 10-2014-0186907, filed on Dec. 23, 2014 with the Korean Intellectual Property Office, the entirety of which is incorporated herein by reference.

### BACKGROUND

The present disclosure relates to a composite electronic component including a plurality of passive devices and a board having the same.

Currently, there is a need for electronic devices having significantly smaller size and various functions so as to meet demands for slimness, lightness, and high performance.

Electronic devices include power semiconductor-based power management integrated circuits (PMIC) for effective control and management of limited battery resources in order to satisfy various service requirements.

However, as various functions are provided in the electronic devices, the number of direct-current (DC) to direct-current (DC) converters provided in the PMICs has increased. Accordingly, the number of passive devices provided in the power input terminals and power output terminals of the PMICs has also increased.

As a result, component mounting areas of the electronic devices have increased, which causes limitations on the miniaturization of the electronic devices.

In addition, severe noise may occur due to wiring patterns of the PMICs and peripheral circuits.

To solve the above problems, research into a composite electronic component in which an inductor and a capacitor are bonded to each other has been conducted to decrease the mounting area of the components in the electronic devices and suppress the occurrence of noise.

The inductor and the capacitor are bonded to each other by an adhesive as described above. In this case, products having fine contact occurring between an external terminal part of the capacitor and a body of the inductor at the time of bonding two components to each other may be produced.

One concern regarding products having the contact occurring between the two components is that insulation resistance (IR) is leaked toward the inductor having relatively lower insulation resistance when voltage is applied to the capacitor within a circuit, and thus the insulation resistance of the capacitor is decreased.

### SUMMARY

One aspect of the present disclosure may provide a composite electronic component in which a component mounting area may be decreased in a driving power supply system and a board having the same.

Another aspect of the present disclosure may also provide a composite electronic component capable of suppressing occurrences of noise in a driving power supply system, and a board having the same.

According to one aspect of the present disclosure, a composite electronic component comprises a composite body including a capacitor and an inductor bonded to each other, the capacitor including a ceramic body in which a plurality of dielectric layers and first and second internal electrodes disposed to face each other with dielectric layers interposed between the first and second internal electrodes are stacked, and the inductor including a magnetic body including a coil part; an input terminal disposed on a first end surface of the composite body and connected to the coil part of the inductor; an output terminal including a first output terminal disposed on a second end surface of the composite body and connected to the coil part of the inductor and a second output terminal disposed on the second end surface of the composite body and connected to the first internal electrodes of the capacitor; and a ground terminal disposed on the first end surface of the composite body and connected to the second internal electrodes of the capacitor, wherein a bonded surface between the inductor and the capacitor is provided with insulating layers.

The magnetic body may comprise a stacked plurality of magnetic layers having conductive patterns formed thereon and the conductive patterns may configure the coil part.

The inductor may have a thin film form in which the magnetic body includes an insulating substrate and a coil formed on at least one surface of the insulating substrate.

The magnetic body may include a core and a winding coil wound around the core.

According to another aspect of the present disclosure, a composite electronic component comprises an input terminal receiving power converted by a power manager; a power stabilizer stabilizing the power and including a composite body including a capacitor and an inductor bonded to each other, the capacitor including a ceramic body in which a plurality of dielectric layers and first and second internal electrodes disposed to face each other with dielectric layers interposed between the first and second internal electrodes are stacked, the inductor including a magnetic body including a coil part, and a bonded surface between the inductor and the capacitor being provided with insulating layers; an output terminal supplying the stabilized power; and a ground terminal.

The input terminal may be disposed on a first end surface of the composite body, the output terminal may include a first output terminal disposed on a second end surface of the composite body and connected to the coil part of the inductor and a second output terminal disposed on the second end surface of the composite body and connected to the first internal electrodes of the capacitor; and the ground terminal may be disposed on the first end surface of the composite body and is connected to the second internal electrodes of the capacitor.

The capacitor may be bonded to a side surface of the inductor.

The insulating layers may be spacers disposed between the second output terminal of the composite body and the magnetic body of the inductor and between the ground terminal of the composite body and the magnetic body of the inductor, respectively, such that the second output terminal and the ground terminal of the composite body are spaced apart from the magnetic body of the inductor.

The spacers may include at least one selected from the group consisting of ceramic, glass, and an organic insulating material.

The insulating layers may be provided as bonding sheets disposed on the bonded surface between the inductor and the capacitor such that the inductor and the capacitor are spaced apart from each other.

The bonding sheet may include at least one selected from the group consisting of ceramic, glass, and an organic insulating material.

According to another aspect of the present disclosure, a composite electronic component may include an input terminal receiving power converted by a power manager, a power stabilizer stabilizing the power and including a composite body including a capacitor and an inductor bonded to each other, the capacitor including a ceramic body in which a plurality of dielectric layers and first and second internal electrodes disposed to face each other with respective dielectric layers interposed between the first and second internal electrodes are stacked, the inductor including a magnetic body including a coil part, and a bonded surface between the inductor and the capacitor being provided with insulating layers, an output terminal supplying the stabilized power, and a ground terminal for a ground.

According to another aspect of the present disclosure, a board having a composite electronic component may include a printed circuit board on which three or more electrode pads are formed, the composite electronic component as described above disposed on the printed circuit board, and solders connecting the electrode pads and the composite electronic component.

### BRIEF DESCRIPTION OF DRAWINGS

The above and other aspects, features and advantages of the present disclosure will be more clearly understood from the following detailed description taken in conjunction with the accompanying drawings.

FIG. 1 is a perspective view schematically illustrating a composite electronic component according to an exemplary embodiment in the present disclosure.

FIG. 2 is a perspective view schematically illustrating an inside of a composite electronic component of FIG. 1 according to a first exemplary embodiment in the present disclosure.

FIG. 3 is a perspective view schematically illustrating an inside of a composite electronic component of FIG. 1 according to a second exemplary embodiment in the present disclosure.

FIG. 4 is a perspective view schematically illustrating an inside of a composite electronic component of FIG. 1 according to a third exemplary embodiment in the present disclosure.

FIG. 5 is a plan view illustrating internal electrodes used in a multilayer ceramic capacitor in the composite electronic component shown in FIG. 1.

FIG. 6 is an equivalent circuit diagram of the composite electronic component shown in FIG. 1;

FIG. 7 is a perspective view schematically illustrating a composite electronic component according to another exemplary embodiment in the present disclosure.

FIG. 8 is a view illustrating a driving power supply system supplying driving power to a predetermined terminal requiring the driving power through a battery and a power manager.

FIG. 9 is a view illustrating a pattern in which the driving power supply system is disposed.

FIG. 10 is a circuit diagram of a composite electronic component according to an exemplary embodiment in the present disclosure.

FIG. 11 is a view illustrating the disposition pattern of the driving power supply system to which the composite electronic component according to the exemplary embodiment in the present disclosure is applied.

FIG. 12 is a perspective view illustrating a board in which the composite electronic component of FIG. 1 is mounted on a printed circuit board.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

Composite Electronic Component

Hereinafter, exemplary embodiments will be described in detail with reference to the accompanying drawings.

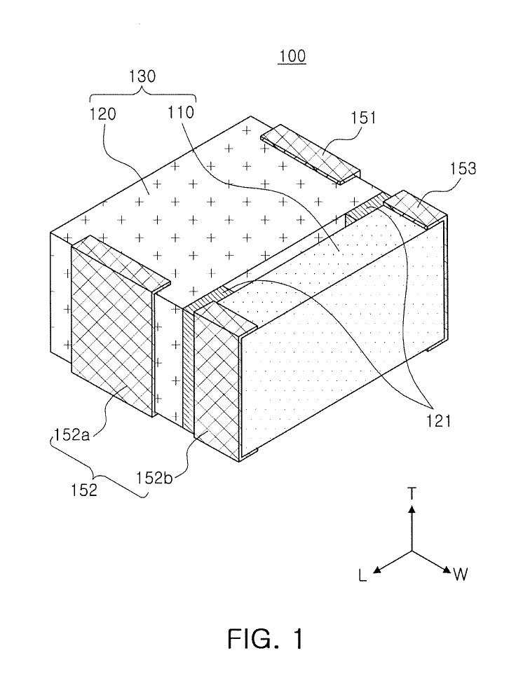

FIG. 1 is a perspective view schematically illustrating a composite electronic component according to an exemplary embodiment.

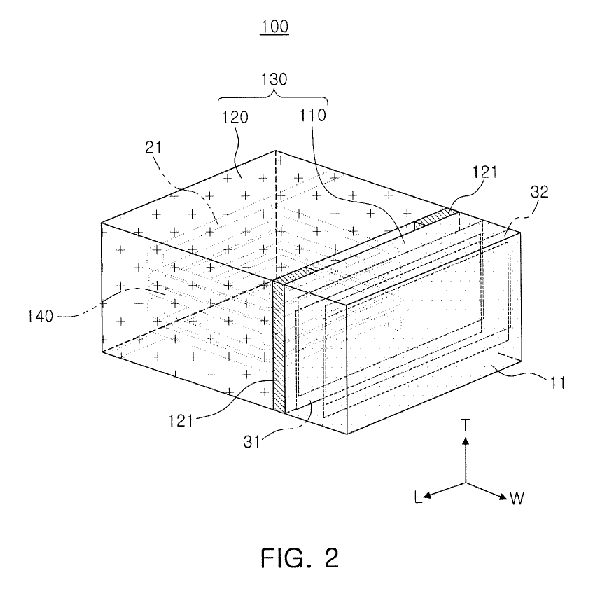

FIG. 2 is a perspective view schematically illustrating an inside of a composite electronic component of FIG. 1 according to a first exemplary embodiment.

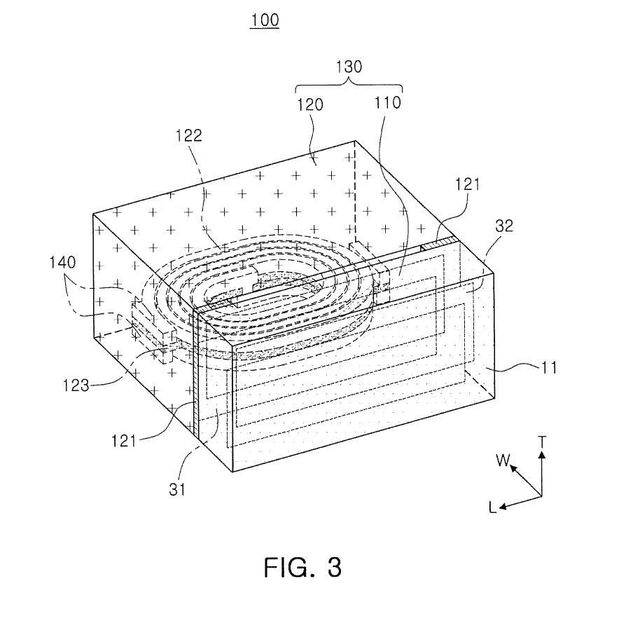

FIG. 3 is a perspective view schematically illustrating an inside of a composite electronic component of FIG. 1 according to a second exemplary embodiment.

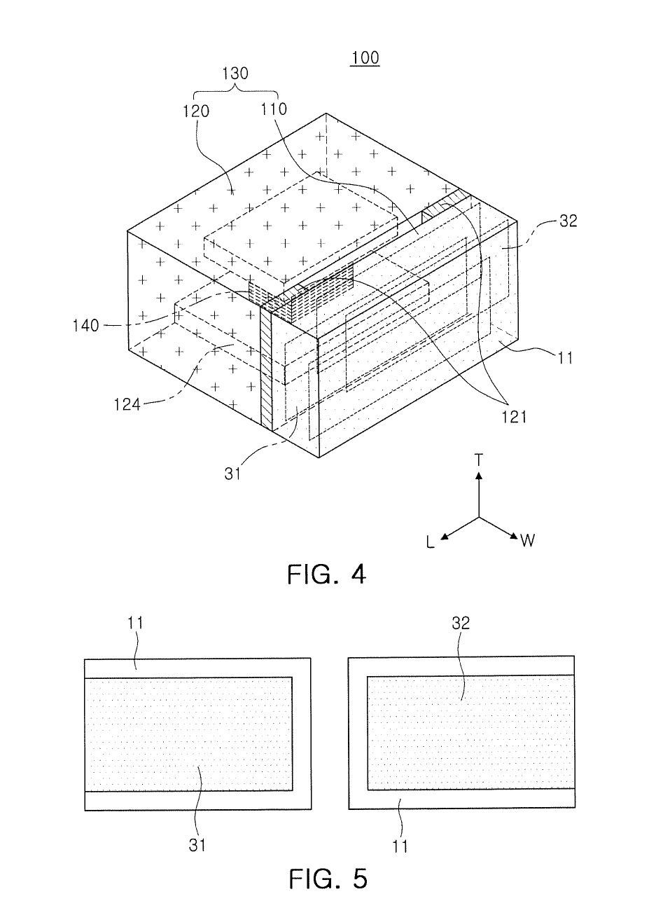

FIG. 4 is a perspective view schematically illustrating an inside of a composite electronic component of FIG. 1 according to a third exemplary embodiment.

FIG. 5 is a plan view illustrating internal electrodes used in a multilayer ceramic capacitor in the composite electronic component shown in FIG. 1.

Referring to FIG. 1, in the composite electronic component, according to an exemplary embodiment, a “length direction” refers to an “L” direction of FIG. 1, a “width direction” refers to a “W” direction of FIG. 1, and a “thickness direction” refers to a “T” direction of FIG. 1. Here, the “thickness direction” refers to a direction in which dielectric layers of a capacitor are stacked, for instance, a “stacking direction”.

Meanwhile, the length direction, the width direction, and the thickness direction of the composite electronic component are the same as those of a capacitor and an inductor as described below.

In addition, in an exemplary embodiment, the composite electronic component may have upper and lower surfaces opposing each other, first and second end surfaces connecting between the upper and lower surfaces and disposed in the length direction, and first and second side surfaces connecting the upper and lower surfaces and disposed in the width direction. A shape of the composite electronic component is not particularly limited, but may be hexahedral as shown.

In addition, the first and second end surfaces of the composite electronic component in the length direction and the first and second side surfaces thereof in the width direction may be the same as first and second end surfaces of a capacitor and an inductor in the length direction and first and second side surfaces thereof in the width direction, respectively, as described below.

Meanwhile, the composite electronic component may have a form in which the capacitor and the inductor are bonded to each other. In a case in which the capacitor is bonded to a side surface of the inductor, an upper surface of the composite electronic component refers to an upper surface of the inductor and the capacitor and a lower surface thereof refers to a lower surface of the inductor and the capacitor.

Referring to FIGS. 1 through 5, a composite electronic component 100, according to an exemplary embodiment may include a composite body 130 having a capacitor 110 and an inductor 120 bonded to each other, wherein the capacitor 110 includes a ceramic body in which a plurality of dielectric layers 11 and first and second internal electrodes 31 and 32 disposed to face each other with each of the dielectric layers 11 interposed therebetween are stacked, and the inductor 120 includes a magnetic body including a coil part 140.

In the present exemplary embodiment, the composite body 130 may have upper and lower surfaces opposing each other, and first and second end surfaces in a length direction and first and second side surfaces in a width direction connecting the upper and lower surfaces.

A shape of the composite body 130 is not particularly limited, but may be hexahedral as shown.

Meanwhile, according to an exemplary embodiment, the capacitor 110 may be bonded to the side surface of the inductor 120, but is not limited thereto. Therefore, the inductor 120 may be disposed in various forms.

The composite body 130 may be formed by bonding the capacitor 110 and the inductor 120. However, a method of forming the composite body 130 is not particularly limited.

According to the exemplary embodiment, a bonded surface between the inductor 120 and the capacitor 110 is further provided with insulating layers 121.

The bonded surface between the inductor 120 and the capacitor 110 is further provided with the insulating layers 121 to constantly maintain a distance between the inductor and the capacitor during the bonding process, thereby improving a reduction in insulation resistance (IR).

Generally, research into composite electronic components in which an inductor and a capacitor are bonded to each other has been conducted to decrease a mounting area of the components in electronic devices and suppress the occurrence of noise.

However, the inductor and the capacitor are bonded to each other by an adhesive as described above. In this case, products having fine contact occurring between an external terminal part of the capacitor and a body of the inductor during bonding between the two components may be produced.

As such, products having the contact occurring between the two components have a problem in that insulation resistance (IR) is leaked toward the inductor having relatively lower insulation resistance when voltage is applied to the capacitor within a circuit, and thus the insulation resistance of the capacitor is decreased.

According to an exemplary embodiment, the bonded surface between the inductor 120 and the capacitor 110 is further provided with the insulating layers 121 which serve as a spacer between the bonded components, thereby preventing insulation resistance of the capacitor from decreasing even after the components are bonded to each other.

For instance, the insulating layers 121 prevent the fine contact from occurring between the external terminal part of the capacitor 110 and the body of the inductor 120, thereby preventing the insulation resistance of the capacitor from decreasing due to the leakage of insulation resistance (IR) toward the inductor having relatively lower insulation resistance.

Therefore, according to the exemplary embodiment, a bonding interface between the inductor 120 and the capacitor 110 is provided by the insulating layers 121, and thus the inductor 120 and the capacitor 110 may be bonded to each other while being spaced apart from each other.

Referring to FIG. 1, in the composite electronic component, according to the exemplary embodiment, the insulating layers 121 may be spacers each disposed between a second output terminal 152b and a ground terminal 153 of the composite body 130 and the magnetic body of the inductor 120 so that the second output terminal 152b and the ground terminal 153 of the composite body 130 are spaced apart from the magnetic body of the inductor 120.

For instance, the insulating layers 121 may be the spacers disposed so that the second output terminal 152b and the ground terminal 153 corresponding to the external terminal part of the capacitor 110 are spaced apart from the magnetic body of the inductor 120.

Therefore, two spacers may be disposed to be spaced apart from each other so that the second output terminal 152b does not contact the magnetic body of the inductor 120 and the ground terminal 153 does not contact the magnetic body of the inductor 120.

A shape of the spacers is not particularly limited, and therefore the spacers may have a shape in which the spacers are disposed on the bonded surface of the magnetic body of the inductor 120 with areas which may cover the second output terminal 152b and the ground terminal 153.

The spacers may include one or more of ceramic, glass, and an organic insulating material.

The organic insulating material is not particularly limited. For example, the organic insulating material may be an epoxy resin or acrylic resin.

The spacers may be disposed using only ceramic or glass. In this case, the spacers may have a shape in which both sides of the spacers are thinly applied with an adhesive to bond the two components.

A thickness of the insulating layers 121 having the spacer shape according to the exemplary embodiment is not particularly limited. For example, the thickness of the spacer may be 0.5 μm to 100 μm.

A thickness of the insulating layer 121 is controlled to be 0.5 μm to 100 μm to prevent the fine contact from occurring between the external terminal part of the capacitor 110 and the body of the inductor 120, thereby preventing the insulation resistance of the capacitor from decreasing due to the leakage of insulation resistance (IR) toward the inductor having relatively lower insulation resistance.

When the thickness of the insulating layer 121 is less than 0.5 μm, the thickness of the insulating layer 121 is too reduced, thereby causing the occurrence of voltage leakage.

Meanwhile, when the thickness of the insulating layer 121 exceeds 100 μm, a size of a product is increased, thereby causing the problem that the product is not miniaturized.

Hereinafter, the capacitor 110 and the inductor 120 configuring the composite body 130 will be described below in detail.

According to an exemplary embodiment, the magnetic body configuring the inductor 120 may include the coil part 140.

The inductor 120 is not particularly limited and may be, for example, a multilayer type inductor, a thin film type inductor, and a winding type inductor.

The multilayer type inductor may be manufactured by thickly printing electrodes on thin ferrite or glass ceramic sheets, stacking several sheets on which coil patterns are printed, and forming a connection between internal conducting wires through via-holes.

The thin film type inductor may be manufactured by forming coil conducting wires on a ceramic substrate by thin film sputtering or plating and providing a ferrite material.

The winding type inductor may be manufactured by winding wires (coil conducting wires) around a core.

Referring to FIG. 2, in a composite electronic component according to a first exemplary embodiment, the inductor 120 may be the multilayer type inductor.

In further detail, the magnetic body may have a form in which a plurality of magnetic layers 21 having conductive patterns formed thereon are stacked, and the conductive patterns may configure the coil part 140.

Referring to FIG. 3, in a composite electronic component, according to a second exemplary embodiment, the inductor 120 may be a thin film type inductor.

More specifically, the inductor 120 may have a thin film form in which the magnetic body includes an insulating substrate 123 and coil patterns formed on at least one surface of the insulating substrate 123.

The magnetic body may be formed by filling upper and lower portions of the insulating substrate 123 having the coil patterns formed on at least one surface thereof with magnetic material 122.

Referring to FIG. 4, in a composite electronic component, according to a third exemplary embodiment, the inductor 120 may be a winding type inductor.

More specifically, the inductor 120 may have a form in which the magnetic body includes a core 124 and winding coils wound around the core 124.

Referring to FIGS. 2 through 4, the first and second internal electrodes 31 and 32 of the capacitor 110 are stacked perpendicular to a mounting surface, but are not limited thereto. Therefore, the first and second internal electrodes 31 and 32 of the capacitor 110 may be stacked in parallel with the mounting surface.

The magnetic layer 21 and the magnetic material 122 may be formed of an Ni—Cu—Zn based material, an Ni—Cu—Zn—Mg based material, or an Mn—Zn based material, but are not limited thereto.

According to an exemplary embodiment, the inductor 120 may be a power inductor that may be applied with a large amount of current.

The power inductor may be a high efficiency inductor of which the inductance is changed less than that of a general inductor when applying DC current. For instance, it may be considered that the power inductor includes DC bias characteristics (change in inductance depending on the applied DC current) as well as the functions of the general inductor.

For instance, the composite electronic component, according to an exemplary embodiment, may be used in a power management integrated circuit (PMIC) and may include a high efficiency inductor of which inductance is changed less than that of a general inductor when applying DC current.

Meanwhile, the ceramic body configuring the capacitor 110 may be formed by stacking the plurality of dielectric layers 11, and a plurality of internal electrodes 31 and 32 (first and second internal electrodes, in order) may be disposed in the ceramic body to be spaced apart from each other with each of the dielectric layers interposed therebetween.

The dielectric layers 11 may be formed by sintering ceramic green sheets including a ceramic powder, an organic solvent, and an organic binder. The ceramic powder, a high-k material, may be a barium titanate (BaTiO₃) based material, a strontium titanate (SrTiO₃) based material, or the like, but is not limited thereto.

Meanwhile, according to an exemplary embodiment, the first internal electrodes 31 may be exposed to a second end surface of the composite body 130 in a length direction and the second internal electrodes 32 may be exposed to a first end surface of the composite body 130 in a length direction, but are not necessarily limited thereto.

According to the exemplary embodiment, the first and second internal electrodes 31 and 32 may be formed of a conductive paste including a conductive metal.

The conductive metal may be nickel (Ni), copper (Cu), palladium (Pd), or alloys thereof, but is not limited thereto.

The first and second internal electrodes 31 and 32 may be printed on the ceramic green sheets forming the dielectric layers 11, using the conductive paste by printing methods such as a screen printing method or a gravure printing method.

The ceramic green sheets having the internal electrodes printed thereon may be alternately stacked and sintered to form the ceramic body.

Pattern shapes of the first and second internal electrodes 31 and 32 are shown in FIG. 5 but are not limited thereto. Therefore, the pattern shapes of the first and second internal electrodes 31 and 32 may be variously changed.

The capacitor may serve to control voltage supplied from a power management integrated circuit (PMIC).

The composite electronic component, according to the exemplary embodiment, may include an input terminal 151 disposed on the first end surface of the composite body 130 in the length direction and connected to the coil part 140 of the inductor 120, an output terminal 152 including a first output terminal 152a disposed on the second end surface of the composite body 130 in the length direction and connected to the coil part 140 of the inductor 120 and a second output terminal 152b disposed on the second end surface of the composite body 130 in the length direction and connected to the first internal electrode 31 of the capacitor 110, and a ground terminal 153 disposed on the first end surface of the composite body 130 in the length direction and connected to the second internal electrode 32 of the capacitor 110.

The input terminal 151 and the first output terminal 152a may be connected to the coil part 140 of the inductor 120 to serve as the inductor in the composite electronic component.

In addition, the second output terminal 152b is connected to the first internal electrodes 31 of the capacitor 110 and the second internal electrodes 32 of the capacitor 110 are connected to the ground terminal 153 to serve as the capacitor in the composite electronic component.

The input terminal 151, the output terminal 152, and the ground terminal 153 may be formed of a conductive paste including a conductive metal.

The conductive metal may be nickel (Ni), copper (Cu), tin (Sn), or alloys thereof, but is not limited thereto.

The conductive paste may further include an insulating material but is not limited thereto. For example, the insulating material may be glass.

A method of forming the input terminal 151, the output terminal 152, and the ground terminal 153 is not particularly limited. Therefore, the input terminal 151, the output terminal 152, and the ground terminal 153 may be formed by dipping the ceramic body or may be formed by other methods such as a printing method, a plating method, or the like.

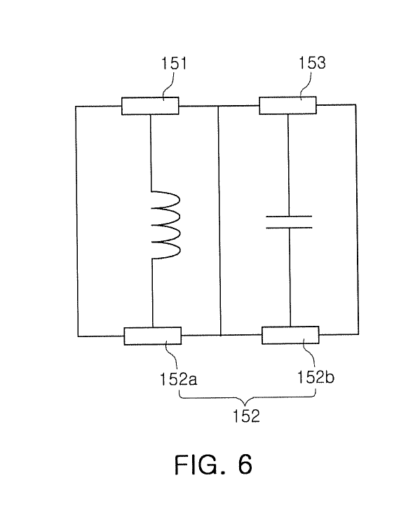

FIG. 6 is an equivalent circuit diagram of the composite electronic component shown in FIG. 1.

Referring to FIG. 6, the composite electronic component, according to an exemplary embodiment may include the inductor 120 and the capacitor 110 bonded to each other unlike in the related art. Therefore, the inductor 120 and the capacitor 110 may be designed to have the shortest distance therebetween, thereby decreasing noise.

In addition, the inductor 120 and the capacitor 110 are bonded to each other to significantly decrease the area in which they are mounted in the PMIC, thereby easily securing the mounting space.

In addition, a cost required for mounting the composite electronic component may be decreased.

Meanwhile, as electronic devices include various functions, the number of DC to DC converters included in PMICs has increased. In addition, the number of passive devices that should be included in a power input terminal and a power output terminal of PMICs has also increased.

In this case, the mounting area of components in electronic devices cannot but increase, which may limit miniaturization of electronic devices.

In addition, severe noise may occur due to PMICs and wiring patterns of peripheral circuits of PMICs.

To solve the above problems, research into a composite electronic component in which an inductor and a capacitor are vertically bonded to each other has been conducted to decrease the mounting area of the components in electronic devices and suppress the occurrence of noise.

However, when the inductor and the capacitor are vertically disposed as described above, a magnetic flux generated from the inductor affects the internal electrodes of the capacitor, thereby causing a problem in that the self resonant frequency (SRF) moves toward a low frequency.

When the self resonant frequency (SRF) moves toward the low frequency as described above, a frequency domain of the inductor which may be used in the exemplary embodiment may be narrow.

For instance, since the function of the inductor is not exhibited in a high frequency band which is equal to or higher than the self resonant frequency (SRF), the self resonant frequency (SRF) moves toward the low frequency, and thus the available frequency band may be limited.

However, according to the exemplary embodiment, the capacitor 110 may be bonded to the side surface of the inductor 120 to significantly decrease the effect of the magnetic flux generated from the inductor on the internal electrodes of the capacitor, thereby preventing the self resonant frequency (SRF) from being changed.

For instance, according to the exemplary embodiment, the inductor 120 and the capacitor 110 may be designed to have the shortest distance therebetween to decrease noise and prevent the self resonant frequency (SRF) from being changed, thereby preventing the range of the inductor available in the low frequency from being limited.

Meanwhile, as the size of the composite electronic composite is decreased, the internal magnetic layer for blocking the magnetic field of the inductor becomes gradually reduced in the size thereof, thereby causing a problem in that Q characteristics are decreased.

The Q characteristics are defined as a loss of an element or efficiency reduction, which means that the larger the Q value, the lower the loss and the higher the efficiency becomes.

For instance, according to the exemplary embodiment, the capacitor 110 is bonded to the side surface of the inductor 120 to significantly decrease the effect of each component on each other, thereby preventing the Q characteristics of the components from deteriorating.

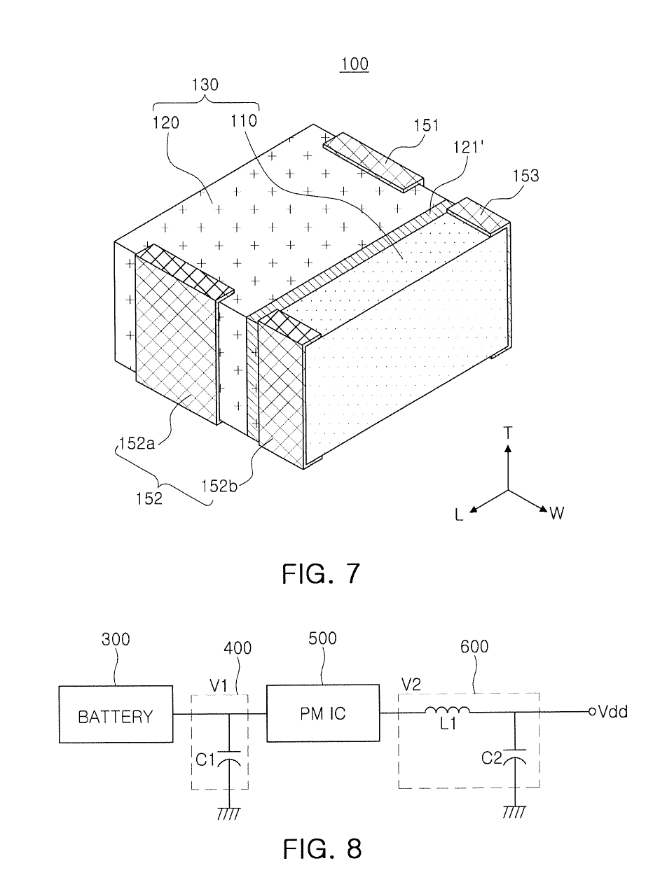

FIG. 7 is a perspective view schematically illustrating a composite electronic component according to another exemplary embodiment.

Referring to FIG. 7, in a composite electronic component, the bonded surface between the inductor 120 and the capacitor 110 is further provided with an insulating layer 121′, in which the insulating layer 121′ is a bonding sheet disposed on the bonded surface between the inductor 120 and the capacitor 110 so that the inductor 120 and the capacitor 110 are spaced apart from each other.

The insulating layer 121′ is disposed on the bonded surface between the inductor 120 and the capacitor 110 in a bonding sheet form to allow the inductor and the capacitor to keep a predetermined distance at the time of the bonding process, thereby improving the reduction in insulation resistance (IR) and preventing the adhesive from flowing down to prevent a poor appearance due to spreading of the adhesive, etc.

For instance, since the insulating layer 121′ is disposed on the bonded surface between the inductor 120 and the capacitor 110 in the bonding sheet form, the second output terminal 152b and the ground terminal 153 which correspond to the external terminal parts of the capacitor 110 may serve as the spacers to allow the second output terminal 152b and the ground terminal 153 to be spaced apart from the magnetic body of the inductor 120.

The insulating layer 121′ has the bonding sheet form and the insulating layer 121′ may be formed in a shape in which it covers the entirety of the bonded surface between the inductor 120 and the capacitor 110, but is not limited thereto.

The bonding sheet may include one or more of ceramic, glass, and an organic insulating material.

The organic insulating material is not particularly limited. For example, the organic insulating material may be an epoxy resin or acrylic resin.

The bonding sheet may be disposed using only ceramic or glass. In this case, the bonding sheet may have a shape in which both sides of the bonding sheet are thinly applied with an adhesive to bond the two components.

A thickness of the insulating layer 121′ having the bonding sheet form according to the exemplary embodiment is not particularly limited. For example, the thickness of the bonding sheet form may be 1.0 μm to 30 μm.

The thickness of the insulating layer 121′ is controlled to be 1.0 μm to 30 μm to secure greater insulation even if the thickness of the insulating layer is reduced, as compared with a method for applying a liquefied insulating material.

As a result, the insulating layer 121′ prevents the micro contact occurring between the external terminal part of the capacitor 110 and the body of the inductor 120, thereby preventing the insulation resistance of the capacitor from decreasing due to the leakage of insulation resistance (IR) toward the inductor having relatively lower insulation resistance.

When the thickness of the insulating layer 121′ is less than 1.0 μm, the thickness of the insulating layer 121′ is too reduced, thereby causing the occurrence of voltage leakage.

Meanwhile, when the thickness of the insulating layer 121′ exceeds 3 μm, the size of the product is increased, thereby preventing the product from being miniaturized.

FIG. 8 is a view illustrating a driving power supply system supplying driving power to a predetermined terminal requiring the driving power through a battery and a power manager.

Referring to FIG. 8, the driving power supply system may include a battery 300, a first power stabilizer 400, a power manager 500, and a second power stabilizer 600.

The battery 300 may supply power to the power manager 500. Here, the power supplied to the power manager 500 by the battery 300 will be defined as a first power.

The first power stabilizer 400 may stabilize the first power V₁ and supply the stabilized first power to the power manager. In detail, the first power stabilizer 400 may include a capacitor C₁ formed between a connection terminal between the battery 300 and the power manager 500 and a ground. The capacitor C₁ may decrease noise included in the first power.

In addition, the capacitor C₁ may be charged with electric charges. Further, in a case in which the power manager 500 instantaneously consumes a large amount of current, the capacitor C₁ may discharge the electric charges charged therein, thereby suppressing a voltage variation in the power manager 500.

It may be preferable that the capacitor C₁ is a high capacitance capacitor in which the stacked number of dielectric layers is equal to or more than 300.

The power manager 500 may serve to convert power input to the electronic devices into power appropriate for the electronic devices and distribute, charge, and control the power. Therefore, the power manager 500 may generally include a DC to DC converter.

In addition, the power manager 500 may be implemented as the power management integrated circuit (PMIC).

The power manager 500 may convert the first power V₁ into a second power V₂. The second power V₂ may be required by an active device such as an integrated circuit (IC), or the like, connected to an output terminal of the power manager 500 to receive the driving power from the power manager 500.

The second power stabilizer 600 may stabilize the second power V₂ and transfer the stabilized second power to an output terminal V_{dd}. The active device such as an integrated circuit (IC), or the like, receiving the driving power from the power manager 500 may be connected to the output terminal V_{dd}.

In detail, the second power stabilizer 600 may include an inductor L₁ disposed between the power manager 500 and the output terminal V_{dd} and connected to the power manager 500 and the output terminal V_{dd} in series. In addition, the second power stabilizer 600 may include a capacitor C₂ formed between a connection terminal between the power manager 500 and the output terminal V_{dd} and a ground.

The second power stabilizer 600 may decrease noise included in the second power V₂.

In addition, the second power stabilizer 600 may stably supply power to the output terminal V_{dd}.

The inductor L₁ may preferably be a power inductor that may be applied to a large amount of current.

The power inductor may be a high efficiency inductor of which the inductance is changed less than a general inductor when applying a DC current. For instance, it may be considered that the power inductor includes the DC bias characteristics (change in inductance depending on the applied DC current) as well as the functions of the general inductor.

In addition, the capacitor C₂ may preferably be a high capacitance capacitor.

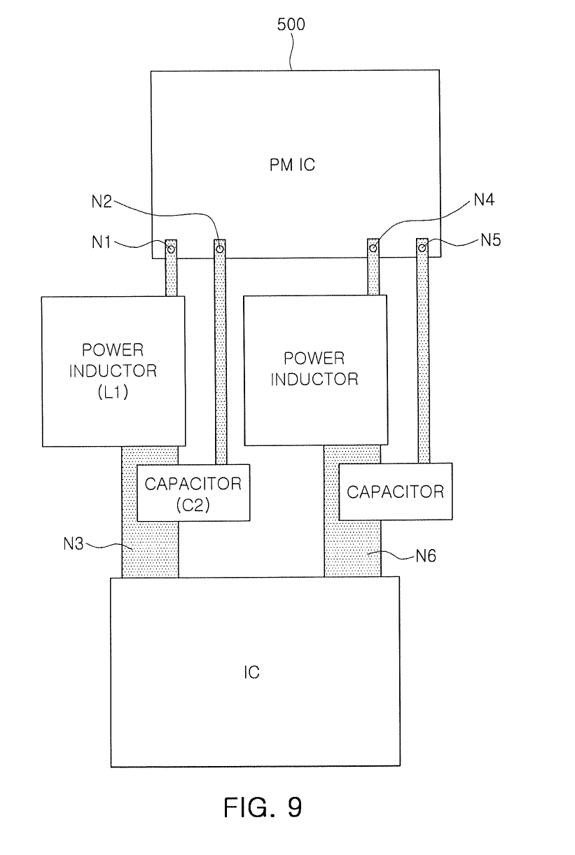

FIG. 9 is a view illustrating a pattern in which the driving power supply system is disposed.

Referring to FIG. 9, a pattern in which the power manager 500, the power inductor L₁, and the second capacitor C₂ are disposed may be confirmed.

Generally, the power manager (PMIC) 500 may include several to tens of DC to DC converters. In addition, in order to implement a function of the DC to DC converter, a power inductor and a high capacitance capacitor may be required in each DC to DC converter.

Referring to FIG. 9, the power manager 500 may have predetermined terminals N1 and N2. The power manager 500 may receive power from the battery and convert the power using the DC to DC converter. In addition, the power manager 500 may supply the converted power through the first terminal N1. The second terminal N2 may be a ground terminal.

Here, the first power inductor L₁ and the second capacitor C₂ may receive power from the first terminal N1, stabilize the power, and supply driving power through a third terminal N3. Therefore, the first power inductor L₁ and the second capacitor C₂ may serve as the second power stabilizer.

Since fourth to sixth terminals N4 to N6 shown in FIG. 9 perform the same functions as those of the first to third terminals N1 to N3, a detailed description thereof will be omitted.

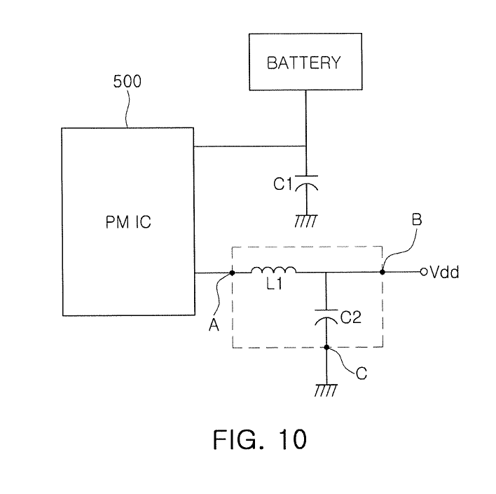

FIG. 10 is a circuit diagram of a composite electronic component according to an exemplary embodiment.

Referring to FIG. 10, the composite electronic component may include an input terminal part A (input terminal), the power stabilizer, an output terminal part B (output terminal), and a ground terminal part C (ground terminal).

The power stabilizer may include the power inductor L₁ and the second capacitor C₂.

The composite electronic component may perform the function of the second power stabilizer described above.

The input terminal part A may receive power converted by the power manager 500.

The power stabilizer may stabilize the power received from the input terminal part A.

The output terminal part B may supply the stabilized power to an output terminal V_{dd}.

The ground terminal part C may connect the power stabilizer to a ground.

Meanwhile, the power stabilizer may include the power inductor L₁ connected between the input terminal part A and the output terminal part B and the second capacitor C₂ connected between the ground terminal part C and the output terminal part.

Referring to FIG. 10, the power inductor L₁ and the second capacitor C₂ share the output terminal part B with each other, whereby an interval between the power inductor L₁ and the second capacitor C₂ may be decreased.

As such, the composite electronic component may be formed by implementing the power inductor and the high capacitance capacitor provided in an output power terminal of the power manager 500 as a single component. Therefore, in the composite electronic component, a degree of integration of devices may be improved.

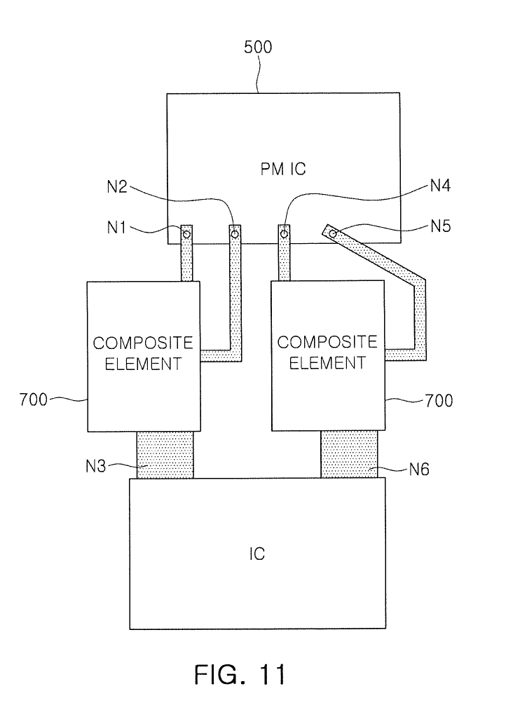

FIG. 11 is a view showing the disposition pattern of the driving power supply system to which the composite electronic component, according to the exemplary embodiment, is applied.

Referring to FIG. 11, it may be confirmed that the second capacitor C₂ and the power inductor L₁ shown in FIG. 9 have been replaced by the composite electronic component according to an exemplary embodiment.

As described above, the composite electronic component may serve as the second power stabilizer.

In addition, the second capacitor C₂ and the power inductor L₁ may be replaced by the composite electronic component according to the exemplary embodiment, thereby significantly decreasing a length of a wiring. In addition, the number of disposed devices is decreased, and thus the devices may be optimally disposed.

For instance, according to the exemplary embodiment, the power manager, the power inductor, and the high capacitance capacitor may be disposed to be as close to each other as possible, and the wiring of the power line may be designed to be short and thick, thereby decreasing noise.

Further, according to the exemplary embodiment, two components (second capacitor and power inductor) are implemented as a single composite electronic component, thereby decreasing the area in which the components are mounted on the PCB. According to the present exemplary embodiment, the area in which the components are mounted may be decreased by about 30 to 60%, as compared with the existing disposition pattern.

Further, according to the exemplary embodiment, the power manager 500 may supply the power to the IC receiving the driving power through the shortest wiring.

Further, according to the exemplary embodiment, the composite electronic component may significantly decrease the effect of the magnetic flux generated from the inductor on the internal electrodes of the capacitor due to the capacitor being disposed on the side surface of the inductor to prevent the self resonant frequency (SRF) from being changed.

Further, according to the exemplary embodiment, the composite electronic component may prevent Q characteristics of the component from deteriorating due to the capacitor being disposed on the side surface of the inductor.

Board Having Multilayer Ceramic Capacitor

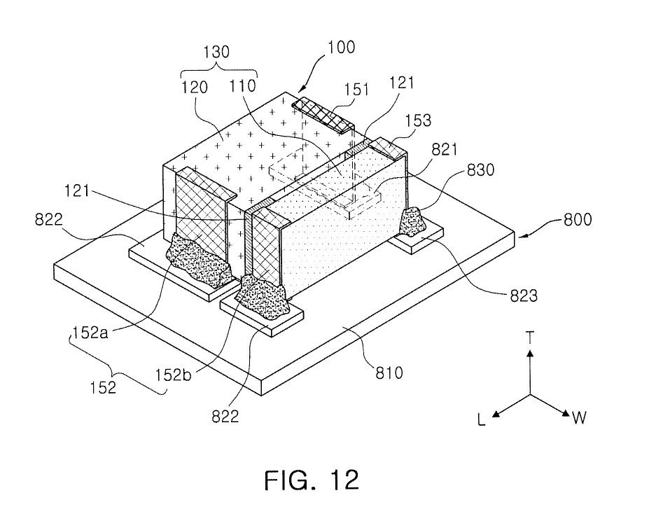

FIG. 12 is a perspective view showing a board in which the composite electronic component of FIG. 1 is mounted on a printed circuit board.

Referring to FIG. 12, a board 800 having a composite electronic component 100 according to the exemplary embodiment may include a printed circuit board 810 on which the composite electronic component 100 is mounted and more than three electrode pads 821, 822, and 823 formed on an upper surface of the printed circuit board 810.

The electrode pads may include the first to third electrode pads 821, 822, and 823 connected to the input terminal 151, the output terminal 152, and the ground terminal 153 of the composite electronic component, respectively.

Here, the input terminal 151, the output terminal 152, and the ground terminal 153 of the composite electronic component 100 may be electrically connected to the printed circuit board 810 by solders 830 in a state in which they are positioned on the first to third electrode pads 821, 822, and 823, respectively, to contact the first to third electrode pads 821, 822, and 823, respectively.

As set forth above, according to exemplary embodiments, the composite electronic component having a decreased mounting area of component in the driving power supply system may be provided.

In addition, according to exemplary embodiments, the composite electronic component capable of suppressing occurrences of noise in the driving power supply system may be provided.

Further, according to exemplary embodiments, the composite electronic component may significantly decrease the effect of the inductor on the internal electrodes of the capacitor due to the capacitor being disposed on the side surface of the inductor to prevent the self resonant frequency (SRF) from being changed.

Further, according to the exemplary embodiment, the composite electronic component may prevent Q characteristics of the component from deteriorating due to the capacitor being disposed on the side surface of the inductor.

Further, according to exemplary embodiments, the insulating layer may be disposed on the bonded surface between the inductor and the capacitor to constantly maintain the distance between the inductor and the capacitor at the time of the bonding process, thereby improving the reduction in insulation resistance (IR).

While exemplary embodiments have been shown and described above, it will be apparent to those skilled in the art that modifications and variations could be made without departing from the spirit and scope of the present disclosure as defined by the appended claims.

What is claimed is:

1. A composite electronic component, comprising:
a composite body including a capacitor and an inductor bonded to each other, the capacitor including a ceramic body in which a plurality of dielectric layers and first and second internal electrodes disposed to face each other with dielectric layers interposed between the first and second internal electrodes are stacked, and the inductor including a magnetic body including a coil part;
an input terminal disposed on a first end surface of the composite body and connected to the coil part of the inductor;
an output terminal including a first output terminal disposed on a second end surface of the composite body and connected to the coil part of the inductor and a second output terminal disposed on the second end surface of the composite body and connected to the first internal electrodes of the capacitor; and
a ground terminal disposed on the first end surface of the composite body and connected to the second internal electrodes of the capacitor,
wherein a bonded surface between the inductor and the capacitor is provided with insulating layers.

2. The composite electronic component of claim 1, wherein the insulating layers are spacers disposed between the second output terminal of the composite body and the magnetic body of the inductor and between the ground terminal of the composite body and the magnetic body of the inductor, respectively, so that the second output terminal and the ground terminal of the composite body are spaced apart from the magnetic body of the inductor.

3. The composite electronic component of claim 2, wherein the spacers include at least one selected from the group consisting of ceramic, glass, and an organic insulating material.

4. The composite electronic component of claim 1, wherein the insulating layers are bonding sheets disposed on the bonded surface between the inductor and the capacitor such that the inductor and the capacitor are spaced apart from each other.

5. The composite electronic component of claim 4, wherein the bonding sheets include at least one selected from the group consisting of ceramic, glass, and an organic insulating material.

6. The composite electronic component of claim 1, wherein the magnetic body comprises a stacked plurality of magnetic layers having conductive patterns formed thereon and the conductive patterns configure the coil part.

7. The composite electronic component of claim 1, wherein the inductor has a thin film form in which the magnetic body includes an insulating substrate and a coil formed on at least one surface of the insulating substrate.

8. The composite electronic component of claim 1, wherein the magnetic body includes a core and a winding coil wound around the core.

9. The composite electronic component of claim 1, wherein the capacitor is bonded to a side surface of the inductor.

10. A composite electronic component, comprising:
an input terminal receiving power converted by a power manager;
a power stabilizer stabilizing the power and including a composite body including a capacitor and an inductor bonded to each other, the capacitor including a ceramic body in which a plurality of dielectric layers and first and second internal electrodes disposed to face each other with dielectric layers interposed between the first and second internal electrodes are stacked, the inductor including a magnetic body including a coil part, and a bonded surface between the inductor and the capacitor being provided with insulating layers;
an output terminal supplying the stabilized power; and
a ground terminal.

11. The composite electronic component of claim 10, wherein the input terminal is disposed on a first end surface of the composite body,
the output terminal includes a first output terminal disposed on a second end surface of the composite body and connected to the coil part of the inductor and a second output terminal disposed on the second end surface of the composite body and connected to the first internal electrodes of the capacitor; and
the ground terminal is disposed on the first end surface of the composite body and is connected to the second internal electrodes of the capacitor.

12. The composite electronic component of claim 10, wherein the capacitor is bonded to a side surface of the inductor.

13. The composite electronic component of claim 10, wherein the insulating layers are spacers disposed between the second output terminal of the composite body and the magnetic body of the inductor and between the ground terminal of the composite body and the magnetic body of the inductor, respectively, such that the second output terminal and the ground terminal of the composite body are spaced apart from the magnetic body of the inductor.

14. The composite electronic component of claim 13, wherein the spacers include at least one selected from the group consisting of ceramic, glass, and an organic insulating material.

15. The composite electronic component of claim 10, wherein the insulating layers are provided as bonding sheets disposed on the bonded surface between the inductor and the capacitor such that the inductor and the capacitor are spaced apart from each other.

16. The composite electronic component of claim 15, wherein the bonding sheet includes at least one selected from the group consisting of ceramic, glass, and an organic insulating material.
